(19) United States
(12) Patent Application Publication
(10) Pub. No.: US 2023/0051542 A1
(43) Pub. Date: Feb. 16, 2023

(54) BATTERY PROTECTION CIRCUIT BOARD AND SOLDERING METHOD

(71) Applicant: Shennan Circuits Co., Ltd., Shenzhen (CN)

(72) Inventor: FUYU XIANG, Shenzhen (CN)

(21) Appl. No.: 17/506,659

(22) Filed: Oct. 20, 2021

Related U.S. Application Data
(63) Continuation of application No. PCT/CN2021/121085, filed on Sep. 27, 2021.

(30) Foreign Application Priority Data
Aug. 12, 2021 (CN) 202110926126.1

(51) Int. Cl. H02J 7/00; H01M 10/42; B23K 1/002

(52) U.S. Cl. CPC H02J 7/0029; H01M 10/425; B23K 1/002

(57) ABSTRACT

The present disclosure provides a battery protection circuit board and a preparation method thereof. The battery protection circuit board includes a first battery protection board and a second battery protection board, a hardness of the first battery protection board being greater than a hardness of the second battery protection board. The soldering method includes: preparing a first to-be-soldered region of the first battery protection board and preparing a second to-be-soldered region of the second battery protection board; preparing a first copper paste in the first to-be-soldered region of the first battery protection board and preparing a second copper paste in the second to-be-soldered region of the second battery protection board; and bonding the first to-be-soldered region of the first battery protection board and the second to-be-soldered region of the second battery protection board by the first copper paste and the second copper paste.

### CROSS REFERENCE

The present application is a continuation-application of International (PCT) Patent Application No. PCT/CN2021/121085, filed on Sep. 27, 2021, which claims foreign priority of Chinese Patent Application No. 202110926126.1, filed on Aug. 12, 2021, in the China National Intellectual Property Administration, the entire contents of which are hereby incorporated by reference in its entirety.

### TECHNICAL FIELD

The present disclosure relates to the field of circuit battery protection technologies, and in particular to a battery protection circuit board and a soldering method.

### BACKGROUND

A battery protection board is an integrated circuit board for rechargeable battery protection. The battery protection function is usually achieved by the protection board and other current devices, where the voltage of a battery cell and the current of a charging-and-discharging circuit are required to accurately be monitored at all times under the environment of −40° C. to +85° C., and the on/off of the current circuit is required to be controlled immediately. The battery protection may refer to over-charge protection, over-discharge protection, over-current, short-circuit protection and ultra-high temperature charge and discharge protection. The battery protection board is the security of a mobile phone battery and even the whole mobile phone. With the commercialization of 5G, which brings users a faster Internet experience and more intelligent applications, the hardware cost of mobile phones has gradually increased. Reflected in the battery module, the battery protection circuit board is mostly adopted with a combination of hard and soft board. That is, the battery protection circuit board is divided into a hard board region connected to the battery and a soft board region capable of being freely bent. In the soft board area, a connector is connected to the mobile phone.

The battery protection board is the security of the cell phone battery and even the entire mobile phone. Therefore, mobile phone manufacturers and battery module manufacturers pay special attention to the high reliability of the battery protection board.

To avoid a conductive anodic filament (CAF) failure (such as solder voids) and other long-term reliability risks associated with soldering the soft and hard boards with solder paste, mainstream manufacturers now mostly adopt a soft-and-hard combination board to produce the battery protection circuit board, and the cost thereof is higher compared to the cost of soldering soft and hard boards, thus limiting the development of most low-cost manufacturers.

### SUMMARY OF THE DISCLOSURE

The present disclosure provides a battery protection circuit board and a soldering method, to improve the reliability of the battery protection circuit board.

In order to address the above technical problems, the present disclosure provides a soldering method for a battery protection circuit board, wherein the battery protection circuit board comprises a first battery protection board and a second battery protection board, a hardness of the first battery protection board being greater than a hardness of the second battery protection board, and the soldering method comprises: preparing a first to-be-soldered region of the first battery protection board and preparing a second to-be-soldered region of the second battery protection board; preparing a first copper paste in the first to-be-soldered region of the first battery protection board and preparing a second copper paste in the second to-be-soldered region of the second battery protection board; and bonding the first to-be-soldered region of the first battery protection board and the second to-be-soldered region of the second battery protection board by the first copper paste and the second copper paste.

In some embodiments, the preparing the first to-be-soldered region of the first battery protection board and preparing the second to-be-soldered region of the second battery protection board comprises: defining a first notch in a vertical direction of the first battery protection board and a second notch in a vertical direction of the second battery protection board to form the first to-be-soldered region and the second to-be-soldered region; the preparing the first copper paste in the first to-be-soldered region of the first battery protection board and the preparing the second copper paste in the second to-be-soldered region of the second battery protection board comprise: preparing the first copper paste in the first notch and the preparing the second copper paste in the second notch.

In some embodiments, the bonding the first to-be-soldered region of the first battery protection board and the second to-be-soldered region of the second battery protection board by the first copper paste and the second copper paste comprises: forming a bonding connection between the first copper paste of the first battery protection board and the second copper paste of the second battery protection board by a heating process.

In some embodiments, the preparing the first copper paste in the first to-be-soldered region of the first battery protection board and the preparing the second copper paste in the second to-be-soldered region of the second battery protection board comprise: preparing an adhesive layer around the first notch and preparing another adhesive layer around the second notch.

In some embodiments, after the preparing the first to-be-soldered region of the first battery protection board and preparing the second to-be-soldered region of the second battery protection board, further comprising: preparing a first adhesive layer in a first not-to-be-soldered region of the first battery protection board, and preparing a second adhesive layer in a second not-to-be-soldered region of the second battery protection board; the bonding the first to-be-soldered region of the first battery protection board and the second to-be-soldered region of the second battery protection board by the first copper paste and the second copper paste comprises: adhering the first not-to-be-soldered region of the first battery protection board and the second not-to-be-soldered region of the second battery protection board by the first adhesive layer and the second adhesive layer.

In some embodiments, the second battery protection board comprises a flexible substrate.

In some embodiments, the first battery protection board comprises a multilayer printed circuit board; the first battery protection board defines a pilot hole penetrating the first battery protection board.

In some embodiments, the first battery protection board comprises a first copper layer, a second copper layer, a third copper layer, and a fourth copper layer; a resin layer is arranged between the first copper layer and the second copper layer; a substrate layer is arranged between the second copper layer and the third copper layer; another resin layer is arranged between the third copper layer and the fourth copper layer; the pilot hole penetrates the first copper layer, the second copper layer, the third copper layer, and the fourth copper layer.

In some embodiments, the first copper layer and the second copper layer are arranged symmetrically with the third copper layer and the fourth copper layer; thicknesses of the first copper layer, the second copper layer, the third copper layer, and the fourth copper layer are the same.

In order to address the above technical problems, the present disclosure further provides a soldering method for a battery protection circuit board, wherein the battery protection circuit board comprises a first battery protection board and a second battery protection board, a hardness of the first battery protection board being greater than a hardness of the second battery protection board, and the soldering method comprises: defining a first notch in a vertical direction of the first battery protection board and a second notch in a vertical direction of the second battery protection board to form a first to-be-soldered region of the first battery protection board and a second to-be-soldered region of the second battery protection board; preparing a first copper paste in the first to-be-soldered region of the first battery protection board and preparing a second copper paste in the second to-be-soldered region of the second battery protection board; preparing a first adhesive layer in a first not-to-be-soldered region of the first battery protection board, and preparing a second adhesive layer in a second not-to-be-soldered region of the second battery protection board; bonding the first to-be-soldered region of the first battery protection board and the second to-be-soldered region of the second battery protection board by the first copper paste and the second copper paste; and adhering the first not-to-be-soldered region of the first battery protection board and the second not-to-be-soldered region of the second battery protection board by the first adhesive layer and the second adhesive layer; wherein the first not-to-be-soldered region of the first battery protection board is a region around the first notch of the first battery protection board, and the second not-to-be-soldered region of the second battery protection board is a region around the second notch of the second battery protection board.

In some embodiments, the preparing the first copper paste in the first to-be-soldered region of the first battery protection board and the preparing the second copper paste in the second to-be-soldered region of the second battery protection board comprise: preparing the first copper paste in the first notch and the preparing the second copper paste in the second notch.

In some embodiments, the bonding the first to-be-soldered region of the first battery protection board and the second to-be-soldered region of the second battery protection board by the first copper paste and the second copper paste comprises: forming a bonding connection between the first copper paste of the first battery protection board and the second copper paste of the second battery protection board by a heating process.

In order to address the above technical problems, the present disclosure further provides a battery protection circuit board, comprising a first battery protection board and a second battery protection board, a hardness of the first battery protection board being greater than a hardness of the second battery protection board; wherein a copper paste is arranged in a first to-be-soldered region of the first battery protection board and a second copper paste is arranged in a second to-be-soldered region of the second battery protection board; a first adhesive layer is arranged in a first not-to-be-soldered region of the first battery protection board and a second adhesive layer is arranged in a second not-to-be-soldered region of the second battery protection board; the first to-be-soldered region of the first battery protection board and the second to-be-soldered region of the second battery protection board are bonded by the first copper paste and the second copper paste; the first not-to-be-soldered region of the first battery protection board and the second not-to-be-soldered region of the second battery protection board are adhered by the first adhesive layer and the second adhesive layer.

In some embodiments, the first copper paste of the first battery protection board is perpendicular to the first battery protection board, the second copper paste of the second battery protection board is perpendicular to the second battery protection board, and the first battery protection board and the second battery protection board are bonded by the first copper paste and the second copper paste.

In some embodiments, the first battery protection board comprises a multilayer printed circuit board; the first battery protection board defines a pilot hole penetrating the first battery protection board.

In some embodiments, the first battery protection board comprises a flexible substrate and multilayer printed circuit boards arranged on opposite sides of the flexible substrate.

In some embodiments, the first battery protection board comprises a first copper layer, a second copper layer, a third copper layer, and a fourth copper layer; a resin layer is arranged between the first copper layer and the second copper layer; a substrate layer is arranged between the second copper layer and the third copper layer; another resin layer is arranged between the third copper layer and the fourth copper layer; the pilot hole penetrates the first copper layer, the second copper layer, the third copper layer, and the fourth copper layer.

In some embodiments, the first copper layer and the second copper layer are arranged symmetrically with the third copper layer and the fourth copper layer; thicknesses of the first copper layer, the second copper layer, the third copper layer, and the fourth copper layer are the same.

In some embodiments, the first battery protection board further comprises a first copper layer and a second copper layer arranged on opposite sides of the flexible substrate; a cover layer is arranged on a side surface of the first copper layer away from the flexible substrate, and another cover layer is arranged on a side surface of the second copper layer away from the flexible substrate.

### BRIEF DESCRIPTION OF THE DRAWINGS

In order to more clearly describe the technical solutions in the embodiments of the present disclosure, the following will briefly introduce the drawings required in the description of the embodiments. Obviously, the drawings in the following description are only some embodiments of the present disclosure. For those skilled in the art, other drawings can be obtained based on these drawings without creative work.

FIG. 1 is a flowchart of a soldering method for a battery protection circuit board according to an embodiment of the present disclosure.

FIG. 2 is a structural schematic view of a battery protection hard board according to an embodiment of the present disclosure.

FIG. 3 is a structural schematic view of a battery protection soft board according to an embodiment of the present disclosure.

FIG. 4 is a flowchart of a soldering method for a battery protection circuit board according to an embodiment of the present disclosure.

FIG. 5 is a structural schematic view of a battery protection circuit board according to an embodiment of the present disclosure.

### DETAILED DESCRIPTION

The following will be a clear and complete description of the technical solutions in the embodiments of the present disclosure in conjunction with the accompanying drawings in the embodiments of the present disclosure. Obviously, the described embodiments are only a part of the embodiments of the present disclosure, and not all of them. Based on the embodiments in the present disclosure, all other embodiments obtained by those skilled in the art without making creative labor fall within the scope of the present disclosure.

The terms used in the embodiments of the present disclosure are used solely for the purpose of describing particular embodiments and are not intended to limit the present disclosure. The singular forms of “a” “said” and “the” as used in the embodiments of the present disclosure and the appended claims are also intended to include plural form, unless clearly indicated. Terms “a plurality” generally include at least two, but does not exclude the inclusion of at least one.

It should be understood that the term “and/or” as used herein is simply a description of the association of related objects, indicating that three relationships can exist, e.g., A and/or B, which can mean: A alone, both A and B, and B alone. In addition, the character “/” in this document generally indicates that the before and after associated objects are in an “or” relationship.

It is to be understood that the term “include” “comprise” or any other variant used herein is intended to cover non-exclusive inclusion, such that a process, method, article, or apparatus comprising a set of elements includes not only those elements, but also other elements not explicitly listed, or elements inherent to such process, method, article, or apparatus. Without further limitation, elements defined by the statement “including” do not preclude the existence of additional identical elements in the process, method, article, or apparatus that include the elements.

It should be noted that when there is a directional indication (such as up, down, left, right, forward, back) involved in the embodiments of the present disclosure, the directional indication is only intended to explain a relative position relationship, movement, etc. between components in a particular attitude (as shown in the drawings). When the particular attitude is changed, the directional indication is changed accordingly.

References herein to “embodiments” mean that particular features, structures or characteristics described in connection with the embodiments may be included in at least one embodiment of the present disclosure. The presence of the phrase at each location in the specification does not necessarily mean a same embodiment, nor is it a separate or alternative embodiment that is mutually exclusive with other embodiments. It is understood, both explicitly and implicitly, by those skilled in the art that the embodiments described herein may be combined with other embodiments.

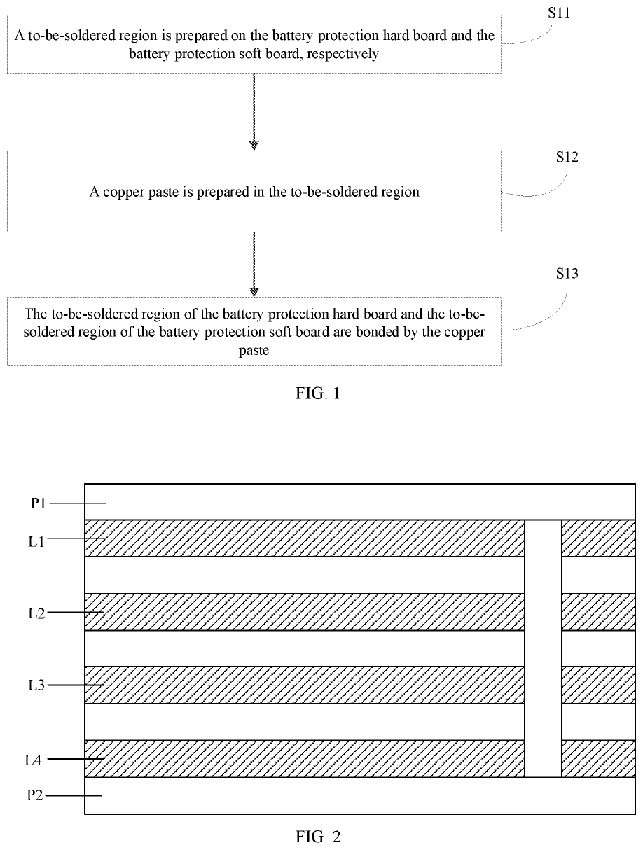

The present disclosure provides a soldering method for a battery protection circuit board. Referring to FIG. 1, FIG. 1 is a flowchart of a soldering method for a battery protection circuit board according to an embodiment of the present disclosure. The battery protection circuit board includes a battery protection hard board and a battery protection soft board. The method may include operations at blocks as followed.

At block S11: A to-be-soldered region is prepared on the battery protection hard board and the battery protection soft board, respectively.

In the embodiment, the battery protection hard board and battery protection soft board may be made separately by a printed circuit board (PCB) and may be two separate boards. The battery protection hard board and the battery protection soft board may be soldered together by soldering. In other embodiments of hard-and-soft combination boards, the battery protection hard board and battery protection soft board have a partial overlap with each other, the two parts of the battery protection circuit board may be made simultaneously.

The battery protection hard board includes a multilayer PCB board and defines a pilot hole. The pilot hole penetrates the battery protection hard board, and the specific structure thereof may be shown in FIG. 2. FIG. 2 is a structural schematic view of a battery protection hard board according to an embodiment of the present disclosure. The battery protection hard board includes at least: a first copper layer L1, a second copper layer L2, a third copper layer L3, and a fourth copper layer L4. A PP resin layer is arranged between the first copper layer L1 and the second copper layer L2. A substrate layer is arranged between the second copper layer L2 and the third copper layer L3, and the substrate layer is a core layer of the battery protection hardboard. Another PP resin layer is arranged between the third copper layer L3 and the fourth copper layer L4. In the embodiment, the first copper layer L1 and the second copper layer L2 are arranged symmetrically with the third copper layer L3 and the fourth copper layer L4, and thicknesses of the four layers are the same. In other embodiments, the first copper layer L1 and the second copper layer L2 may be arranged asymmetrically with the third copper layer L3 and the fourth copper layer L4, which is not limited herein. The battery protection hard board may further define a pilot hole T penetrating the first copper layer L1, the second copper layer L2, the third copper layer L3 and the fourth copper layer L4 of the battery protection hard board.

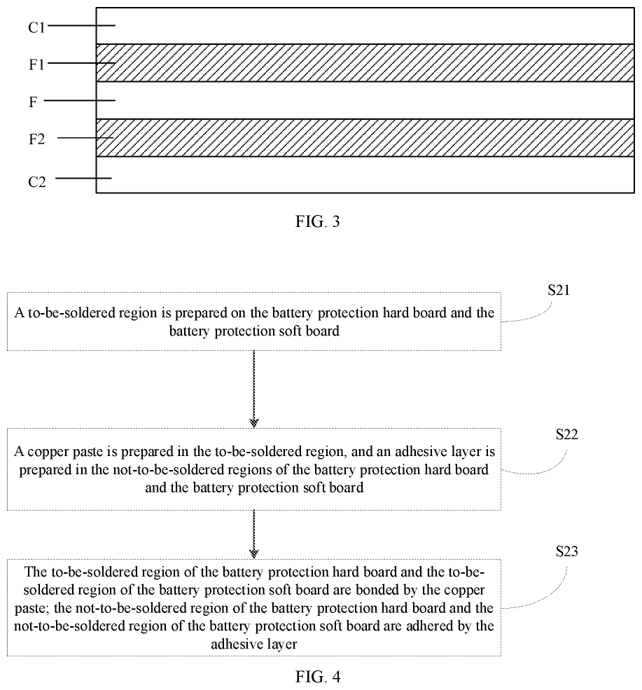

The battery protection soft board includes a flexible substrate, and copper layers and cover layers on both sides of the flexible substrate. Referring to FIG. 3, FIG. 3 is a structural schematic view of a battery protection soft board according to an embodiment of the present disclosure. The battery protection soft board includes a flexible substrate F, and a first copper layer F1 and a second copper layer F2 arranged on opposite sides of the flexible substrate F. A cover layer C1 is arranged on a side surface of the first copper layer F1 away from the flexible substrate F, and another cover layer C2 is arranged on a side surface of the second copper layer F2 away from the flexible substrate F. The cover layers C1 and C2 may be the same or different, and the cover layers C1 and C2 may each include a flexible board protection adhesive layer.

The preparing the to-be-soldered region on the battery protection hard board and the battery protection soft board, respectively may include:

defining a notch in a vertical direction of the battery protection hard board and another notch in a vertical direction of the battery protection soft board to form the to-be-soldered region.

At block S12: A copper paste is prepared in the to-be-soldered region.

Specifically, a copper slurry is filled in the notch in step S12 to fill the notch, such that the copper slurry cools to form the copper paste. The copper paste is a substance that is liquid at high temperatures and becomes a paste when cooled.

At block S13: The to-be-soldered region of the battery protection hard board and the to-be-soldered region of the battery protection soft board are bonded by the copper paste.

Specifically, the copper paste of the battery protection hard board and the copper paste of the battery protection soft board are treated in alignment, and then a bonding reaction between the copper paste of the battery protection hard board and the copper paste on the battery protection soft board is performed by a heating process, such that the copper paste of the battery protection hard board and the copper paste of the battery protection soft board form a connection in the vertical direction.

The beneficial effect of this embodiment is: by preparing the to-be-soldered region on the battery protection hard board and the battery protection soft board respectively, and preparing the copper paste in the to-be-soldered region, the to-be-soldered region on the battery protection hard board and the area to be soldered on the battery protection soft board are bonded by the copper paste, such that the battery protection hard board and the battery protection soft board are interconnected and conductive through the copper paste in the vertical direction of the circuit board, thereby replacing the traditional soldering by solder paste and improving the long-term reliability problems such as circuit failure (CFA) caused by solder voids through solder paste.

The present disclosure provides another soldering method for a battery protection circuit board. Referring to FIG. 4, FIG. 4 is a flowchart of a soldering method for a battery protection circuit board according to an embodiment of the present disclosure. The method may include operations at blocks as followed.

At block S21: A to-be-soldered region is prepared on the battery protection hard board and the battery protection soft board, respectively.

A notch is defined in a vertical direction of the hard battery protection board and a board surface to form the to-be-soldered region of the hard battery protection board, and a not-to-be-soldered region of the hard battery protection board is a region around the notch. A notch is defined in a vertical direction of the soft battery protection board to form the to-be-soldered region and a not-to-be-soldered region of the soft battery protection board.

At block S22: A copper paste is prepared in the to-be-soldered region, and an adhesive layer is prepared in the not-to-be-soldered regions of the battery protection hard board and the battery protection soft board.

Specifically, a copper slurry is filled in the notch, and the adhesive layer is prepared around the notch.

At block S23: The to-be-soldered region of the battery protection hard board and the to-be-soldered region of the battery protection soft board are bonded by the copper paste; the not-to-be-soldered region of the battery protection hard board and the not-to-be-soldered region of the battery protection soft board are adhered by the adhesive layer.

The copper paste of the battery protection hard board and the copper paste of the battery protection soft board are treated in alignment. The adhesive layer of the battery protection hard board and the adhesive layer of the battery protection soft board are treated in alignment. In this way, the copper paste of the battery protection hard board and the copper paste of the battery protection soft board are bonded, and the adhesive layer of the battery protection hard board and the adhesive layer of the battery protection soft board are adhered.

The beneficial effect of this embodiment is: by defining the notches on the battery protection hard board and the battery protection soft board to form the to-be-soldered regions and the not-to-be-soldered regions, and preparing the copper paste in the to-be-soldered region and preparing the adhesive layer in the not-to-be-soldered region, the to-be-soldered region on the battery protection hard board and the area to be soldered on the battery protection soft board are bonded by the copper paste, and the not-to-be-soldered region of the battery protection hard board and the not-to-be-soldered region of the battery protection soft board are adhered by the adhesive layer, thereby improving the reliability of the battery protection hard board and battery protection soft board against circuit inaccessibility problems caused by soldering area limitation and solder voids through solder paste. The present disclosure increases the soldering area of the battery protection hard board and battery protection soft board by soldering the to-be-soldered region by copper paste and the not-to-be-soldered region by adhesive layer, which improves the reliability.

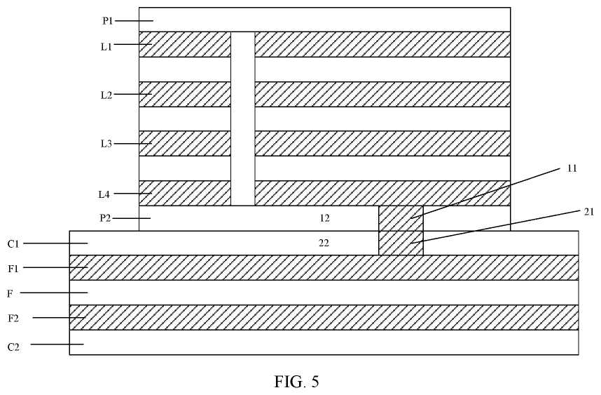

The present disclosure provides a structure of a battery protection circuit board. Referring to FIG. 5, FIG. 5 is a structural schematic view of a battery protection circuit board according to an embodiment of the present disclosure.

The battery protection circuit board includes a battery protection hard board 1 and a battery protection soft board 2. A copper paste is arranged in a to-be-soldered region 11 of the battery protection hard board 1 and a to-be-soldered region 21 of the battery protection soft board 2. An adhesive layer is arranged in a not-to-be-soldered region 12 of the battery protection hard board 1 and a not-to-be-soldered region 22 of the battery protection soft board 2, such that the to-be-soldered region 11 of the battery protection hard board 1 and the to-be-soldered region 21 of the battery protection soft board 2 are bonded by the copper paste, and the not-to-be-soldered region 12 of the battery protection hard board 1 and the not-to-be-soldered region 22 of the battery protection soft board 2 are adhered by the adhesive layer.

The battery protection hard board includes a multilayer PCB board, specifically including a first copper layer L1, a second copper layer L2, a third copper layer L3, and a fourth copper layer L4. A PP resin layer is arranged between the first copper layer L1 and the second copper layer L2. A substrate layer is arranged between the second copper layer L2 and the third copper layer L3, and the substrate layer is a core layer of the battery protection hardboard. Another PP resin layer is arranged between the third copper layer L3 and the fourth copper layer L4. In the embodiment, the first copper layer L1 and the second copper layer L2 are arranged symmetrically with the third copper layer L3 and the fourth copper layer L4, and thicknesses of the four layers are the same. In other embodiments, the first copper layer L1 and the second copper layer L2 may be arranged asymmetrically with the third copper layer L3 and the fourth copper layer L4, which is not limited herein. The battery protection hard board may further define a pilot hole T penetrating the first copper layer L1, the second copper layer L2, the third copper layer L3 and the fourth copper layer L4 of the battery protection hard board. The pilot hole T is filled with a resin. The battery protection hard board 1 is further arranged with cover layers P1 and P2 on opposite sides respectively. A notch is defined on the cover layer P2 on a side of the battery protection hard board 1 near the battery protection soft board 2 to form the to-be-soldered region 11.

The battery protection soft board 2 includes a flexible substrate F, and a first copper layer F1 and a second copper layer F2 arranged on opposite sides of the flexible substrate F. A cover layer C1 is arranged on a side surface of the first copper layer F1 away from the flexible substrate F, and another cover layer C2 is arranged on a side surface of the second copper layer F2 away from the flexible substrate F. The cover layers C1 and C2 may each include a flexible board protection adhesive layer. A notch is defined on the cover layer P1 on a side of the battery protection soft board 2 near the battery protection hard layer 1 to form the to-be-soldered region 21.

The beneficial effect of this embodiment is: by defining the notches on the battery protection hard board and the battery protection soft board to form the to-be-soldered regions and the not-to-be-soldered regions, and preparing the copper paste in the to-be-soldered region and preparing the adhesive layer in the not-to-be-soldered region, the to-be-soldered region on the battery protection hard board and the area to be soldered on the battery protection soft board are bonded by the copper paste, and the not-to-be-soldered region of the battery protection hard board and the not-to-be-soldered region of the battery protection soft board are adhered by the adhesive layer, thereby improving the reliability of the battery protection hard board and battery protection soft board against circuit inaccessibility problems caused by soldering area limitation and solder voids through solder paste. The present disclosure increases the soldering area of the battery protection hard board and battery protection soft board by soldering the to-be-soldered region by copper paste and the not-to-be-soldered region by adhesive layer, which improves the reliability.

The above is only an implementation of the present disclosure, not to limit the scope of the present disclosure. Any equivalent structure or equivalent process transformation made by using the specification and the attached drawings of the present disclosure, or directly or indirectly applied in other related technical fields, are equally included in the scope of the present disclosure.

What is claimed is:

1. A soldering method for a battery protection circuit board, wherein the battery protection circuit board comprises a first battery protection board and a second battery protection board, a hardness of the first battery protection board being greater than a hardness of the second battery protection board, and the soldering method comprises:
preparing a first to-be-soldered region of the first battery protection board and preparing a second to-be-soldered region of the second battery protection board;
preparing a first copper paste in the first to-be-soldered region of the first battery protection board and preparing a second copper paste in the second to-be-soldered region of the second battery protection board; and
bonding the first to-be-soldered region of the first battery protection board and the second to-be-soldered region of the second battery protection board by the first copper paste and the second copper paste.

2. The soldering method according to claim 1, wherein the preparing the first to-be-soldered region of the first battery protection board and preparing the second to-be-soldered region of the second battery protection board comprises:
defining a first notch in a vertical direction of the first battery protection board and a second notch in a vertical direction of the second battery protection board to form the first to-be-soldered region and the second to-be-soldered region;
the preparing the first copper paste in the first to-be-soldered region of the first battery protection board and the preparing the second copper paste in the second to-be-soldered region of the second battery protection board comprise:
preparing the first copper paste in the first notch and the preparing the second copper paste in the second notch.

3. The soldering method according to claim 2, wherein the bonding the first to-be-soldered region of the first battery protection board and the second to-be-soldered region of the second battery protection board by the first copper paste and the second copper paste comprises:
forming a bonding connection between the first copper paste of the first battery protection board and the second copper paste of the second battery protection board by a heating process.

4. The soldering method according to claim 2, wherein the preparing the first copper paste in the first to-be-soldered region of the first battery protection board and the preparing the second copper paste in the second to-be-soldered region of the second battery protection board comprise:
preparing an adhesive layer around the first notch and preparing another adhesive layer around the second notch.

5. The soldering method according to claim 1, after the preparing the first to-be-soldered region of the first battery protection board and preparing the second to-be-soldered region of the second battery protection board, further comprising:
preparing a first adhesive layer in a first not-to-be-soldered region of the first battery protection board, and preparing a second adhesive layer in a second not-to-be-soldered region of the second battery protection board;
the bonding the first to-be-soldered region of the first battery protection board and the second to-be-soldered region of the second battery protection board by the first copper paste and the second copper paste comprises:
adhering the first not-to-be-soldered region of the first battery protection board and the second not-to-be-soldered region of the second battery protection board by the first adhesive layer and the second adhesive layer.

6. The soldering method according to claim 1, wherein the second battery protection board comprises a flexible substrate.

7. The soldering method according to claim 1, wherein the first battery protection board comprises a multilayer printed circuit board;
the first battery protection board defines a pilot hole penetrating the first battery protection board.

8. The soldering method according to claim 7, wherein the first battery protection board comprises a first copper layer, a second copper layer, a third copper layer, and a fourth copper layer; a resin layer is arranged between the first copper layer and the second copper layer; a substrate layer is arranged between the second copper layer and the third copper layer; another resin layer is arranged between the third copper layer and the fourth copper layer;
the pilot hole penetrates the first copper layer, the second copper layer, the third copper layer, and the fourth copper layer.

9. The soldering method according to claim 8, wherein the first copper layer and the second copper layer are arranged symmetrically with the third copper layer and the fourth copper layer;
thicknesses of the first copper layer, the second copper layer, the third copper layer, and the fourth copper layer are the same.

10. A soldering method for a battery protection circuit board, wherein the battery protection circuit board comprises a first battery protection board and a second battery protection board, a hardness of the first battery protection board being greater than a hardness of the second battery protection board, and the soldering method comprises:
defining a first notch in a vertical direction of the first battery protection board and a second notch in a vertical direction of the second battery protection board to form a first to-be-soldered region of the first battery protection board and a second to-be-soldered region of the second battery protection board;
preparing a first copper paste in the first to-be-soldered region of the first battery protection board and preparing a second copper paste in the second to-be-soldered region of the second battery protection board;
preparing a first adhesive layer in a first not-to-be-soldered region of the first battery protection board, and preparing a second adhesive layer in a second not-to-be-soldered region of the second battery protection board;
bonding the first to-be-soldered region of the first battery protection board and the second to-be-soldered region of the second battery protection board by the first copper paste and the second copper paste; and
adhering the first not-to-be-soldered region of the first battery protection board and the second not-to-be-soldered region of the second battery protection board by the first adhesive layer and the second adhesive layer;
wherein the first not-to-be-soldered region of the first battery protection board is a region around the first notch of the first battery protection board, and the second not-to-be-soldered region of the second battery protection board is a region around the second notch of the second battery protection board.

11. The soldering method according to claim 10, wherein the preparing the first copper paste in the first to-be-soldered region of the first battery protection board and the preparing the second copper paste in the second to-be-soldered region of the second battery protection board comprise:
preparing the first copper paste in the first notch and the preparing the second copper paste in the second notch.

12. The soldering method according to claim 11, wherein the bonding the first to-be-soldered region of the first battery protection board and the second to-be-soldered region of the second battery protection board by the first copper paste and the second copper paste comprises:
forming a bonding connection between the first copper paste of the first battery protection board and the second copper paste of the second battery protection board by a heating process.

13. The soldering method according to claim 10, wherein the first battery protection board comprises a flexible substrate and multilayer printed circuit boards arranged on opposite sides of the flexible substrate.

14. A battery protection circuit board, comprising a first battery protection board and a second battery protection board, a hardness of the first battery protection board being greater than a hardness of the second battery protection board;
wherein a copper paste is arranged in a first to-be-soldered region of the first battery protection board and a second copper paste is arranged in a second to-be-soldered region of the second battery protection board; a first adhesive layer is arranged in a first not-to-be-soldered region of the first battery protection board and a second adhesive layer is arranged in a second not-to-be-soldered region of the second battery protection board; the first to-be-soldered region of the first battery protection board and the second to-be-soldered region of the second battery protection board are bonded by the first copper paste and the second copper paste; the first not-to-be-soldered region of the first battery protection board and the second not-to-be-soldered region of the second battery protection board are adhered by the first adhesive layer and the second adhesive layer.

15. The battery protection circuit board according to claim 14, wherein the first copper paste of the first battery protection board is perpendicular to the first battery protection board, the second copper paste of the second battery protection board is perpendicular to the second battery protection board, and the first battery protection board and the second battery protection board are bonded by the first copper paste and the second copper paste.

16. The battery protection circuit board according to claim 14, wherein the first battery protection board comprises a multilayer printed circuit board;
the first battery protection board defines a pilot hole penetrating the first battery protection board.

17. The battery protection circuit board according to claim 14, wherein the first battery protection board comprises a flexible substrate and multilayer printed circuit boards arranged on opposite sides of the flexible substrate.

18. The battery protection circuit board according to claim 16, wherein the first battery protection board comprises a first copper layer, a second copper layer, a third copper layer, and a fourth copper layer; a resin layer is arranged between the first copper layer and the second copper layer; a substrate layer is arranged between the second copper layer and the third copper layer; another resin layer is arranged between the third copper layer and the fourth copper layer;
the pilot hole penetrates the first copper layer, the second copper layer, the third copper layer, and the fourth copper layer.

19. The battery protection circuit board according to claim 18, wherein the first copper layer and the second copper layer are arranged symmetrically with the third copper layer and the fourth copper layer;
thicknesses of the first copper layer, the second copper layer, the third copper layer, and the fourth copper layer are the same.

20. The battery protection circuit board according to claim 17, wherein the first battery protection board further comprises a first copper layer and a second copper layer arranged on opposite sides of the flexible substrate;
a cover layer is arranged on a side surface of the first copper layer away from the flexible substrate, and another cover layer is arranged on a side surface of the second copper layer away from the flexible substrate.
